(19) United States
(12) Patent Application Publication
(10) Pub. No.: US 2026/0205113 A1
(43) Pub. Date: Jul. 16, 2026

(54) GATE DRIVER CIRCUIT

(71) Applicant: ROHM CO., LTD., Kyoto-shi (JP)

(72) Inventor: Hisashi SUGIE, Kyoto-shi (JP)

(21) Appl. No.: 19/445,902

(22) Filed: Jan. 12, 2026

(30) Foreign Application Priority Data
Jan. 16, 2025 (JP) 2025-006354

(51) Int. Cl. H03K 17/687; H02M 1/088; H02P 27/00

(52) U.S. Cl. CPC H03K 17/6871; H02M 1/088; H02P 27/00; H03K 2217/0063; H03K 2217/0072

(57) ABSTRACT

A plurality of high-side driver units correspond to a plurality of high-side transistors. A first output sensor asserts a first output detection signal when an output voltage crosses a predetermined first threshold voltage. A timer circuit measures a timing of assertion of the first output detection signal. Each of the plurality of high-side driver units has an adjustable drive strength. A control circuit adjusts the drive strength of each of the high-side driver units such that the timings of assertion of the first output detection signal are aligned when each of the high-side driver units is operated individually.

### CROSS REFERENCE TO RELATED APPLICATIONS

The present invention claims priority under 35 U.S.C. § 119 to Japanese Application No. JP2025-006354, filed on Jan. 16, 2025, the entire contents of which being incorporated herein by reference.

### BACKGROUND

### 1. Technical Field

The present disclosure relates to a gate driver circuit.

### 2. Description of the Related Art

In motor driver circuits, DC/DC converters, and power conversion apparatuses, a half-bridge circuit, an H-bridge circuit, or a three-phase bridge circuit using power transistors (hereinafter collectively referred to as “switching circuits”) is employed.

In a high-power switching circuit, an arm is formed by connecting a plurality of power transistors in parallel. When the gate threshold voltage V_{GS(th)} of the plurality of power transistors varies, they are turned on or turned off in an order based on their respective gate threshold voltages V_{GS(th)}, making it impossible to turn them on or off simultaneously.

When the turn-on/turn-off timings of the plurality of power transistors are shifted relative to each other, a current concentration occurs, leading to accelerated degradation of the power transistor to which current is concentrated. Further, such timing shift may also cause oscillation.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram of a switching circuit according to an embodiment.

FIG. 2 is a diagram for explaining the operation of the switching circuit before calibration.

FIG. 3 is a diagram for explaining calibration of a high-side driver in the switching circuit.

FIG. 4 is a diagram for explaining the operation of the switching circuit after calibration.

FIG. 5 is a diagram for explaining the operation of the switching circuit before calibration.

FIG. 6 is a diagram for explaining calibration of a low-side driver in the switching circuit.

FIG. 7 is a diagram for explaining the operation of the switching circuit after calibration.

FIG. 8 is a circuit diagram of a gate driver circuit according to an embodiment.

FIG. 9 is a waveform diagram illustrating the operation of the gate driver circuit in FIG. 8.

FIG. 10 is a circuit diagram of a motor driving apparatus according to the embodiment.

### DETAILED DESCRIPTION

### Outline of Embodiments

The following is an outline of several exemplary embodiments of the present disclosure. This outline is provided to facilitate a basic understanding of one or more embodiments before a more detailed description presented later and is not intended to limit the scope of the invention or the disclosure. For convenience, the phrase “in one embodiment” may be used to refer to a single embodiment disclosed in this specification or to multiple embodiments (including variations and modifications thereof).

This outline is not intended to be a comprehensive overview of all possible embodiments, nor to identify key elements of all embodiments or to delineate the scope of any or all aspects of the disclosure. The sole purpose of this outline is to present certain concepts of one or more embodiments in a simplified form as a preface to the more detailed description that follows.

In one embodiment, a gate driver circuit is structured to drive an inverter circuit including an upper arm formed by a plurality of parallel-connected high-side transistors. The gate driver circuit includes a plurality of high-side driver units corresponding to the plurality of high-side transistors and each structured to generate a high-side drive voltage to a gate of a corresponding one of the high-side transistors, a first output sensor structured to assert a first output detection signal when an output voltage of the inverter circuit crosses a predetermined first threshold voltage, a control circuit structured to control the plurality of high-side driver units in response to an output command, and a timer circuit structured to measure a timing of assertion of the first output detection signal. Each of the plurality of high-side driver units has an adjustable drive strength. The control circuit is structured to adjust the drive strength of each of the plurality of high-side driver units such that the timings of assertion of the first output detection signal are aligned when each of the plurality of high-side driver units is operated individually, which may enable substantially simultaneous switching among the high-side transistors and contribute to suppressing current concentration.

According to this configuration, the drive strength of the plurality of high-side transistors can be calibrated based on a time required for the output voltage to change. Accordingly, even when characteristics of the plurality of high-side transistors, specifically gate threshold voltages, vary from one another, the timings of turning on the respective high-side transistors may be aligned. As a result, current concentration among the high-side transistors and oscillation of currents flowing through the respective high-side transistors may be suppressed.

The “drive strength” of a driver unit refers to a capability of changing a gate voltage of a high-side transistor, and may be represented by parameters such as (i) a magnitude of a current output from the driver unit, (ii) an output impedance of the driver unit, and (iii) a size (gate width-to-length ratio, W/L) of a transistor included in the driver unit.

In one embodiment, each of the plurality of high-side driver units may be structured to supply a turn-on current to a gate of a corresponding one of the high-side transistors. The drive strength may be a magnitude of the turn-on current.

In one embodiment, the plurality of high-side driver units may be structured to vary a magnitude of the turn-on current over time. An amplitude of a waveform of the turn-on current may be adjustable as the drive strength.

In one embodiment, the control circuit may be structured to increase a magnitude of the turn-on current generated by the plurality of high-side driver units in response to the assertion of the first output detection signal.

In this configuration, the first output detection signal is utilized for calibration of the drive strength of the plurality of high-side driver units and also serves as a trigger for switching a magnitude of the turn-on current. Accordingly, a magnitude of the turn-on current generated by the plurality of high-side driver units can be increased at the same timing.

In one embodiment, the gate driver circuit may further comprise a plurality of high-side gate sensors corresponding to the plurality of high-side transistors and each structured to assert a high-side gate detection signal when a gate-to-source voltage of a corresponding one of the high-side transistors exceeds a predetermined voltage. The control circuit may be structured to decrease a magnitude of the turn-on current generated by a corresponding one of the high-side driver units in response to the assertion of each high-side gate detection signal.

In one embodiment, a lower arm of the inverter circuit may include a plurality of parallel-connected low-side transistors. The gate driver circuit may further comprise a plurality of low-side driver units corresponding to the plurality of low-side transistors and each structured to generate a low-side drive voltage to a gate of a corresponding one of the low-side transistors, and a second output sensor structured to assert a second output detection signal when the output voltage of the inverter circuit crosses a predetermined second threshold voltage. The control circuit may be structured to control the plurality of low-side driver units in response to the output command. Each of the plurality of low-side driver units may have an adjustable drive strength. The control circuit may be structured to adjust the drive strength of each of the plurality of low-side driver units such that the timings of assertion of the second output detection signal are aligned when each of the plurality of low-side driver units is operated individually.

According to this configuration, the drive strength of the plurality of low-side transistors can be calibrated based on a time required for the output voltage to change. Accordingly, even when characteristics of the plurality of low-side transistors, specifically gate threshold voltages, vary from one another, the timings of turning on the respective low-side transistors may be aligned. As a result, current concentration among the low-side transistors and oscillation of currents flowing through the respective low-side transistors may be suppressed.

In one embodiment, each of the plurality of low-side driver units may be structured to supply a turn-on current to a gate of a corresponding one of the low-side transistors, and the drive strength may be a magnitude of the turn-on current.

In one embodiment, the plurality of low-side driver units may be structured to vary a magnitude of the turn-on current over time, and an amplitude of a waveform of the turn-on current may be adjustable as the drive strength.

In one embodiment, the control circuit may be structured to increase a magnitude of the turn-on current generated by the plurality of low-side driver units in response to the assertion of the second output detection signal.

In this configuration, the second output detection signal is utilized for calibration of the drive strength of the plurality of low-side driver units and also serves as a trigger for switching a magnitude of the turn-on current. Accordingly, a magnitude of the turn-on current generated by the plurality of low-side driver units can be increased at the same timing.

In one embodiment, the gate driver circuit may further comprise a plurality of low-side gate sensors corresponding to the plurality of low-side transistors and each structured to assert a low-side gate detection signal when a gate-to-source voltage of a corresponding one of the low-side transistors exceeds a predetermined voltage. The control circuit may be structured to decrease a magnitude of the turn-on current generated by a corresponding one of the low-side driver units in response to the assertion of each low-side gate detection signal.

In one embodiment, the plurality of high-side transistors may be SiC transistors.

In one embodiment, the plurality of high-side transistors may be Si transistors.

In one embodiment, a gate driver circuit is structured to drive an inverter circuit including a lower arm formed by a plurality of parallel-connected low-side transistors. The gate driver circuit comprises a plurality of low-side driver units corresponding to the plurality of low-side transistors and each structured to generate a low-side drive voltage to a gate of a corresponding one of the low-side transistors, a second output sensor structured to assert a second output detection signal when an output voltage of the inverter circuit crosses a predetermined second threshold voltage, a control circuit structured to control the plurality of low-side driver units in response to the output command, and a timer circuit structured to measure a timing of assertion of the second output detection signal. Each of the plurality of low-side driver units has an adjustable drive strength. The control circuit is structured to adjust the drive strength of each of the plurality of low-side driver units such that the timings of assertion of the second output detection signal are aligned when each of the plurality of low-side driver units is operated individually.

In one embodiment, the gate driver circuit may be monolithically integrated on a single semiconductor substrate. The term “monolithically integrated” is intended to encompass cases where all components of the circuit are formed on the semiconductor substrate and cases where primary components of the circuit are integrated on the semiconductor substrate while some passive elements such as resistors or capacitors for adjusting circuit constants are provided outside the substrate. By integrating the circuit on a single chip, a circuit area can be reduced and characteristics of circuit elements may be kept substantially uniform.

In one embodiment, a motor driving apparatus comprises a bridge circuit including an upper arm and a lower arm, and any of the above-described gate driver circuits structured to drive the bridge circuit.

In one embodiment, an electronic apparatus comprises a motor and the above-described motor driving apparatus structured to drive the motor.

### Embodiments

Hereinafter, preferred embodiments will be described with reference to the drawings. The same or equivalent components, members, and processes illustrated in the drawings will be denoted by the same reference numerals, and repeated description will be omitted as appropriate. Further, the embodiments do not limit the disclosure and the invention, but are exemplary, and all features and combinations thereof described in the embodiments are not necessarily essential to the disclosure and the invention.

In the present specification, a “state where a member A is connected to a member B” includes not only a case where the member A and the member B are directly connected physically but also a case where the member A and the member B are indirectly connected via another member that does not substantially affect an electrical connection state or does not impair a function and an effect provided by connection.

Similarly, a “state where a member C is provided between the members A and B” includes not only a case where the members A and C or the members B and C are directly connected but also a case where the members A and C or the members B and C are indirectly connected via another member that does not substantially affect an electrical connection state or does not impair a function and an effect provided by connection.

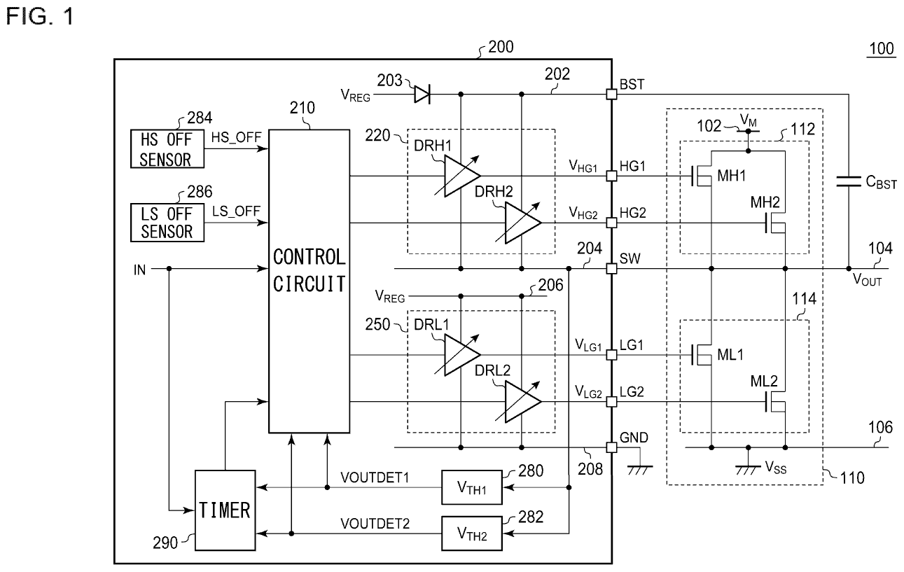

FIG. 1 is a circuit diagram illustrating a switching circuit 100 according to one embodiment. The switching circuit 100 includes a bridge circuit 110 and a gate driver circuit 200. Although only a configuration for one phase of the switching circuit 100 is illustrated here, the switching circuit 100 may be a three-phase circuit or an H-bridge circuit.

The bridge circuit 110 includes an upper arm 112 provided between a power supply line (input line) 102 and an output terminal (output line) 104, and a lower arm 114 provided between the output line 104 and a ground line 106.

The upper arm 112 includes a plurality of N (N≥2) parallel-connected high-side transistors MH1 and MH2, which are independently controllable to be turned on and off. The lower arm 114 includes a plurality of parallel-connected low-side transistors ML1 and ML2. The high-side transistors MH1 and MH2 and the low-side transistors ML1 and ML2 are discrete devices.

In the present embodiment, a case where N=2 is described; however, the number of parallel transistors may be three or more.

The gate driver circuit 200 drives the upper arm 112 and the lower arm 114 of the bridge circuit 110 in response to an input signal IN. The input signal IN is a signal indicating an output voltage V_{OUT} of the bridge circuit 110.

When the input signal IN is at a first level (e.g., HIGH), the gate driver circuit 200 turns on the upper arm 112 and turns off the lower arm 114. In this case, the output voltage V_{OUT} of the bridge circuit 110 becomes a high voltage V_{M}. Conversely, when the input signal IN is at a second level (e.g., LOW), the gate driver circuit 200 turns off the upper arm 112 and turns on the lower arm 114. In this case, the output voltage V_{OUT} of the bridge circuit 110 becomes a low voltage V_{SS}.

A configuration of the gate driver circuit 200 will now be described

A bootstrap capacitor C_{BST} is coupled between a bootstrap pin BST and the output line 104.

A plurality of high-side gate pins HG1 and HG2 correspond to the plurality of high-side transistors MH1 and MH2, and each high-side gate pin HGi (i=1, 2, . . . , N) is coupled to a gate of a corresponding one of the high-side transistors MHi. A switching pin SW is coupled to sources of the high-side transistors MH1 and MH2, drains of the low-side transistors ML1 and ML2, and the output line 104.

A plurality of low-side gate pins LG1 and LG2 correspond to the plurality of low-side transistors ML1 and ML2, and each low-side gate pin LGi (i=1, 2, . . . , N) is coupled to a gate of a corresponding one of the low-side transistors MLi.

A bootstrap line 202 is connected to the bootstrap pin BST. A constant voltage V_{REG} is applied to the bootstrap line 202 through a rectifier element 203. The rectifier element 203 and the bootstrap capacitor C_{BST} form a bootstrap circuit, which maintains a voltage V_{BST} of the bootstrap line 202 at V_{OUT}+V_{REG}−Vf, where Vf is a forward voltage of the rectifier element 203.

The gate driver circuit 200 is a functional IC monolithically integrated on a single semiconductor substrate and comprises a control circuit 210, a high-side driver 220, a low-side driver 250, a first output sensor 280, a second output sensor 282, a high-side off sensor 284, a low-side off sensor 286, and a timer circuit 290. The control circuit 210 controls the high-side driver 220 and the low-side driver 250 in response to the input signal IN.

The high-side driver 220 includes a plurality of high-side driver units DRH1 and DRH2 corresponding to the plurality of high-side transistors MH1 and MH2. The high-side driver 220 is provided between the bootstrap line 202 and a switching line 204.

Each high-side driver unit DRHi controls a high-side drive voltage V_{HGi} generated at a corresponding high-side gate terminal HGi, which is coupled to the gate of the corresponding high-side transistor MHi, and drives the high-side transistor MHi.

The low-side driver 250 includes a plurality of low-side driver units DRL1 and DRL2 corresponding to the plurality of low-side transistors ML1 and ML2. The low-side driver 250 is provided between a power supply line 206 and a ground line 208.

Each low-side driver unit DRLi controls a low-side drive voltage V_{LGi} generated at a corresponding low-side gate terminal LGi, which is coupled to a gate of a corresponding one of the low-side transistors MLi, and drives the low-side transistor MLi.

The control circuit 210 controls the plurality of high-side driver units DRH1 and DRH2 and the plurality of low-side driver units DRL1 and DRL2 in response to the input signal IN, which serves as an output command.

Specifically, when the input signal IN is at a first level (e.g., HIGH), the control circuit 210 controls the high-side driver units DRH1 and DRH2 such that the high-side transistors MH are turned on and controls the low-side driver units DRL1 and DRL2 such that the low-side transistors ML are turned off.

Further, when the input signal IN is at a second level (e.g., LOW), the control circuit 210 controls the high-side driver units DRH1 and DRH2 such that the high-side transistors MH are turned off and controls the low-side driver units DRL1 and DRL2 such that the low-side transistors ML are turned on.

When the input signal IN changes from the first level to the second level, the control circuit 210 controls the high-side driver units DRH1 and DRH2 such that the high-side transistors MH1 and MH2 are turned off first. When the high-side transistors MH1 and MH2 are turned off, the control circuit 210 subsequently controls the low-side driver units DRL1 and DRL2 such that the low-side transistors ML1 and ML2 are turned on. The turning off of the high-side transistors MH1 and MH2 is detected by a high-side off sensor 284. The high-side off sensor 284 monitors gate-to-source voltages of the respective high-side transistors MH1 and MH2 and asserts a high-side off signal HS_OFF when the voltage falls below a predetermined voltage.

When the input signal IN changes from the second level to the first level, the control circuit 210 controls the low-side driver units DRL1 and DRL2 such that the low-side transistors ML1 and ML2 are turned off first. When the low-side transistors ML1 and ML2 are turned off, the control circuit 210 subsequently controls the high-side driver units DRH1 and DRH2 such that the high-side transistors MH1 and MH2 are turned on. The turning off of the low-side transistors ML1 and ML2 is detected by a low-side off sensor 286. The low-side off sensor 286 monitors gate-to-source voltages of the respective low-side transistors ML1 and ML2 and asserts a low-side off signal LS_OFF when the voltage falls below a predetermined voltage.

When turning on the upper arm 112, it is desirable that the plurality of high-side transistors MH1 and MH2 be turned on simultaneously. However, due to variations in electrical characteristics of the high-side transistors MH1 and MH2, they may turn on at different timings. Such variations are particularly noticeable in SiC transistors. Accordingly, the present disclosure is especially effective when the high-side transistors MH1 and MH2 and the low-side transistors ML1 and ML2 are SiC transistors, but the present disclosure is also applicable to Si transistors.

The gate driver circuit 200 has a function of calibrating the high-side driver 220 such that the plurality of high-side transistors MH1 and MH2 are turned on simultaneously.

For this calibration, the plurality of high-side driver units DRH1 and DRH2 that constitute the high-side driver 220 are each structured such that the drive strength can be adjusted independently.

The first output sensor 280 monitors the output voltage V_{OUT} of the bridge circuit 110. The first output sensor 280 asserts a first output detection signal VOUTDET1 when the output voltage V_{OUT} crosses a predetermined first threshold voltage V_{TH1}.

In a calibration mode, the control circuit 210 does not operate the plurality of high-side driver units DRH1 and DRH2 simultaneously but operates them one at a time.

The timer circuit 290 measures a timing of assertion of the first output detection signal VOUTDET1. For example, the timer circuit 290 measures a time from when the input signal IN changes from the second level (LOW) to the first level (HIGH) until the first output detection signal VOUTDET1 is asserted. In other words, the timer circuit 290 measures the timing of assertion of the first output detection signal VOUTDET1 with reference to a change point of the input signal IN. A timing of assertion when the i-th high-side driver unit DRHi is operated is denoted as Toni.

The control circuit 210 adjusts the drive strength of each of the high-side driver units DRH1 and DRH2 such that timings Ton1 and Ton2 of assertion of the first output detection signal VOUTDET1, when the plurality of high-side driver units DRH1 and DRH2 are operated individually, are aligned.

The gate driver circuit 200 also has a function of calibrating the low-side driver 250 such that the plurality of low-side transistors ML1 and ML2 are turned on simultaneously in the lower arm 114.

For this calibration, the plurality of low-side driver units DRL1 and DRL2 that constitute the low-side driver 250 are each structured such that the drive strength can be adjusted independently.

The second output sensor 282 monitors the output voltage V_{OUT} of the bridge circuit 110. The second output sensor 282 asserts a second output detection signal VOUTDET2 when the output voltage V_{OUT} crosses a predetermined second threshold voltage V_{TH2}.

In a calibration mode, the control circuit 210 does not operate the plurality of low-side driver units DRL1 and DRL2 simultaneously but operates them one at a time.

The timer circuit 290 measures the timing of the assertion of the second output detection signal VOUTDET2. For example, the timer circuit 290 measures a time from when the input signal IN changes from a first level (high) to a second level (low) until the assertion of the second output detection signal VOUTDET2. In other words, the timer circuit 290 measures the timing of the assertion of the second output detection signal VOUTDET2 with reference to a change point of the input signal IN. An assertion timing when the i-th low-side driver unit DRLi is operated is denoted as Toni.

The control circuit 210 adjusts the drive strength of each of the low-side driver units DRL1 and DRL2 such that assertion timings Ton1 and Ton2 of the second output detection signal VOUTDET2, obtained when the plurality of low-side driver units DRL1 and DRL2 are operated individually, coincide with each other.

The configuration of the switching circuit 100 has been described above. Its operation will now be described.

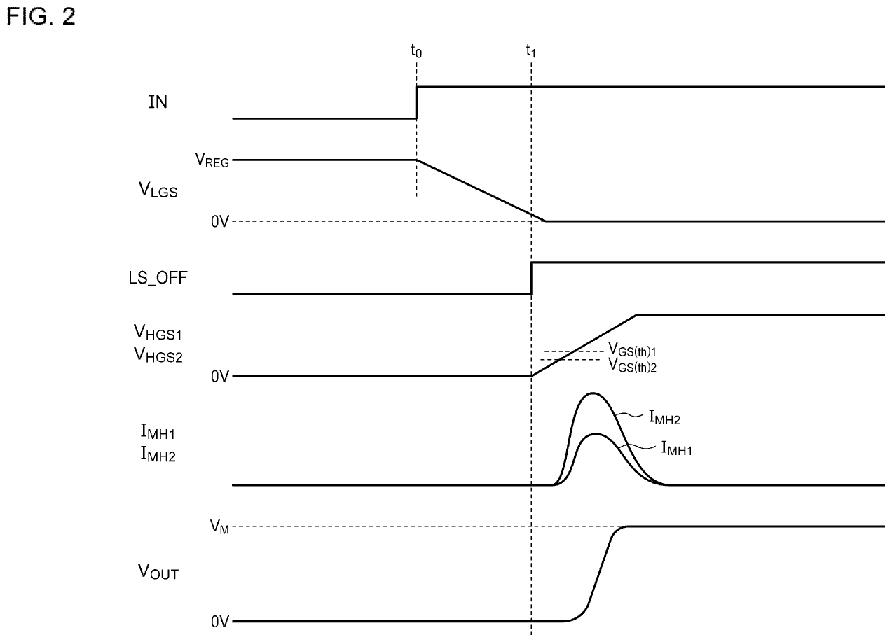

FIG. 2 is a diagram for describing an operation of the switching circuit 100 before calibration. Before a time t₀, the input signal IN is low, the upper arm 112 is off, and the lower arm 114 is on, and an output voltage V_{OUT} is a low voltage (ground potential) of 0 V.

At the time t₀, the input signal IN transitions from low to high. The control circuit 210 controls the low-side driver 250 to reduce gate-to-source voltages V_{LGS} of the low-side transistors ML1 and ML2, thereby turning off the lower arm 114. When the lower arm 114 is turned off at a time t₁, a low-side-off signal LS_OFF is asserted.

In response to the assertion of the low-side-off signal LS_OFF, the control circuit 210 controls the high-side driver 220 to turn on the upper arm 112.

Before calibration, drive strengths of the high-side driver units DRH1 and DRH2 are in initial states, and gate-to-source voltages V_{HGS1} and V_{HGS2} of the respective high-side transistors MH1 and MH2 both increase with the same slope.

It is assumed that gate threshold voltages V_{GS(th)1} of the high-side transistor MH1 and V_{GS(th)2} of the high-side transistor MH2 have variation. For example, when V_{GS(th)2}<V_{GS(th)1}, the high-side transistor MH2 turns on first, followed by the high-side transistor MH1. Thus, current is concentrated into the high-side transistor MH2, and a drain current I_{MH2} of the high-side transistor MH2 becomes larger than a drain current I_{MH1} of the high-side transistor MH1.

As described above, when turn-on timings of the plurality of power transistors MH1 and MH2 deviate, current concentration occurs. There is also a problem in that degradation of a power transistor into which the current is concentrated progresses. In addition, the timing deviation may cause oscillation.

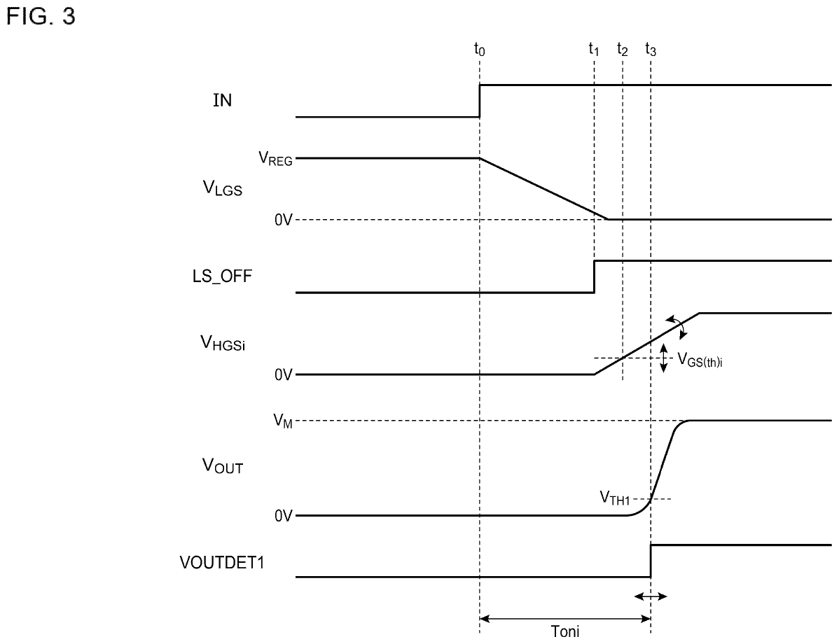

FIG. 3 is a diagram for describing calibration of the high-side driver 220 in the switching circuit 100. As described above, the calibration is performed by sequentially operating the high-side driver units DRH1 and DRH2.

FIG. 3 illustrates waveforms when the i-th (i=1, 2) high-side driver unit DRHi is operated.

Before the time t₀, the input signal IN is low, the upper arm 112 is off, and the lower arm 114 is on, and the output voltage V_{OUT} is a low voltage of 0 V.

At time t₀, the input signal IN transitions from Low to High. The control circuit 210 controls the low-side driver 250 to turn off the lower arm 114. When the lower arm 114 is turned off at time t₁, a low-side-off signal LS_OFF is asserted.

In response to assertion of the low-side-off signal LS_OFF, the control circuit 210 controls a high-side driver unit DRHi of the high-side driver 220. When an output voltage V_{HGi} of the high-side driver unit DRHi rises, a gate-to-source voltage V_{HGSi} of the high-side transistor MHi rises. A rising speed of the gate-to-source voltage V_{HGSi} corresponds to a drive strength of the high-side driver unit DRHi.

At time t₂, when the gate-to-source voltage V_{HGSi} exceeds a gate threshold voltage V_{GS(th)i} of the high-side transistor MHi, the high-side transistor MHi turns on and the output voltage V_{OUT} starts to rise.

Then at time t₃, when the output voltage V_{OUT} exceeds the first threshold voltage V_{TH1}, a first output detection signal VOUTDET1 is asserted.

The timer circuit 290 measures a time Toni from the transition of the input signal IN to assertion of the first output detection signal VOUTDET1, as a timing of assertion of the first output detection signal VOUTDET1.

The timing Toni becomes slower as the gate threshold voltage V_{GS(th)i} of the transistor MHi becomes higher, and becomes faster as the gate threshold voltage V_{GS(th)i} becomes lower.

The control circuit 210 adjusts the drive strength of the high-side driver unit DRHi such that the timing Toni measured for the high-side driver unit DRHi operated individually becomes equal to a timing Tonj measured for another high-side driver unit DRHj operated individually.

That is, when Toni>Tonj, the drive strength of the high-side driver unit DRHi is increased. As a result, a rising speed of the gate-to-source voltage V_{HGSi} of the high-side transistor MHi is increased, Toni is shortened, and Toni approaches Tonj.

Conversely, when Toni<Tonj, the drive strength of the high-side driver unit DRHi is decreased. As a result, the rising speed of the gate-to-source voltage V_{HGSi} of the high-side transistor MHi is decreased, Toni is lengthened, and Toni approaches Tonj.

The procedure for adjusting the high-side driver units DRH1 and DRH2 is not limited to a specific one. For example, a time Ton1 measured for the high-side driver unit DRH1 measured first may be used as a reference, and a drive strength of the high-side driver unit DRH2 may be adjusted such that a time Ton2 measured for the high-side driver unit DRH2 approaches Ton1.

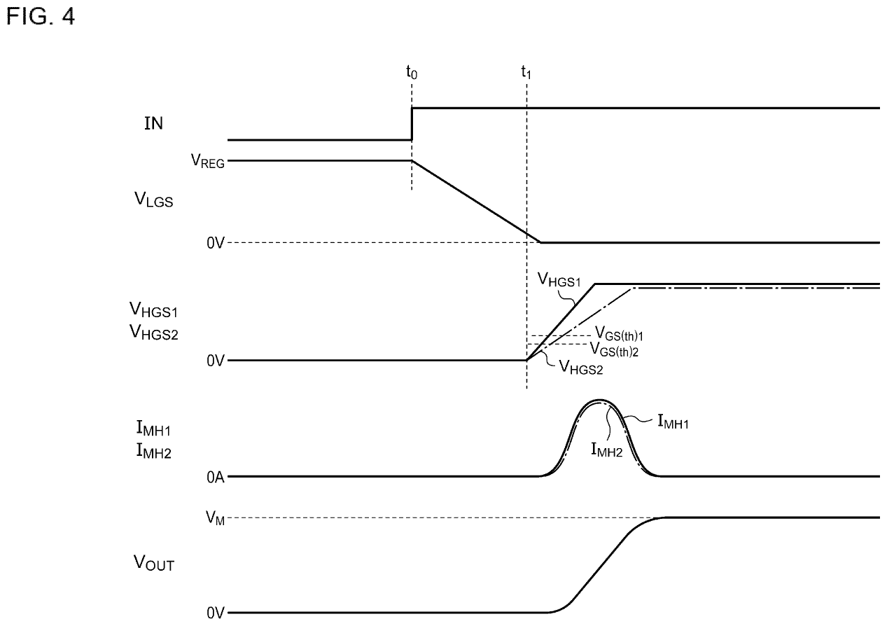

FIG. 4 illustrates operation of the switching circuit 100 after calibration. Prior to time t₀, the input signal IN is Low, the upper arm 112 is turned off, the lower arm 114 is turned on, and the output voltage V_{OUT} is a Low voltage of 0 V.

At time t₀, the input signal IN transitions from Low to High. The control circuit 210 controls the low-side driver 250 to turn off the lower arm 114. When the lower arm 114 is turned off at time t₁, a low-side-off signal LS_OFF is asserted.

In response to assertion of the low-side-off signal LS_OFF, the control circuit 210 controls the high-side driver 220 to turn on the upper arm 112.

After calibration, drive strengths of the high-side driver units DRH1 and DRH2 are optimized. Gate-to-source voltages V_{HGS1} and V_{HGS2} of the high-side transistors MH1 and MH2 rise with different slopes. By the calibration, the high-side transistors MH1 and MH2 turn on substantially simultaneously. Accordingly, the same amount of drain currents I_{MH1} and I_{MH2} flows through the high-side transistors MH1 and MH2, suppressing current concentration.

Next, calibration of the low-side driver 250 will be described.

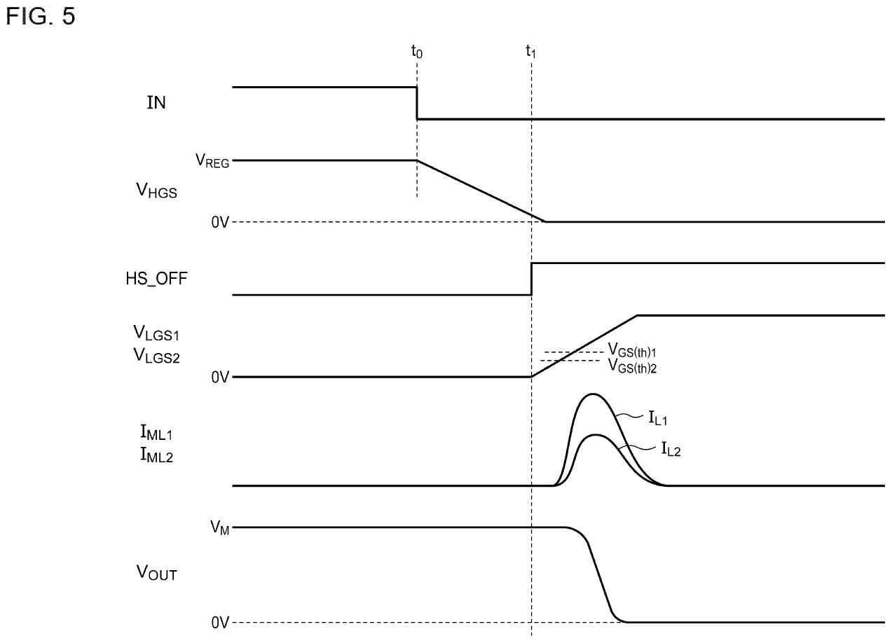

FIG. 5 illustrates operation of the switching circuit 100 before calibration. Prior to time t₀, the input signal IN is High, the upper arm 112 is turned on, the lower arm 114 is turned off, and the output voltage V_{OUT} is a High voltage (input voltage) V_{M}.

At time t₀, the input signal IN transitions from High to Low. The control circuit 210 controls the high-side driver 220 to reduce the gate-to-source voltage V_{HGS}, thereby turning off the upper arm 112. When the upper arm 112 is turned off at time t₁, a high-side-off signal HS_OFF is asserted.

In response to assertion of the high-side-off signal HS_OFF, the control circuit 210 controls the low-side driver 250 to turn on the lower arm 114.

Before calibration, drive strengths of the low-side driver units DRL1 and DRL2 are in an initial state, and gate-to-source voltages V_{LGS1} and V_{LGS2} of the respective low-side transistors ML1 and ML2 rise with the same slope.

Assume that gate-to-source threshold voltages V_{GS(th)1} of the low-side transistor ML1 and V_{GS(th)2} of the low-side transistor ML2 vary. For example, when V_{GS(th)2}<V_{GS(th)1}, the low-side transistor ML2 turns on first and the low-side transistor ML1 turns on subsequently. Accordingly, current concentrates in the low-side transistor ML2, and a drain current I_{ML2} becomes larger than a drain current I_{ML1} flowing through the low-side transistor ML1.

As such, when turn-on timings of the plurality of power transistors ML1 and ML2 deviate, current concentration may occur. Progression of degradation of a transistor that carries concentrated current becomes a concern. Further, timing deviation may potentially cause oscillation.

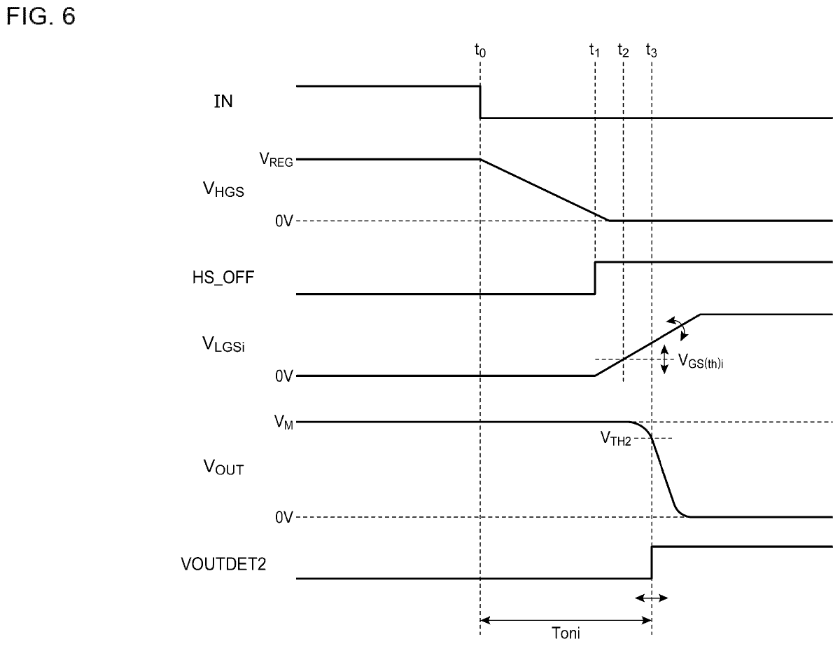

FIG. 6 illustrates calibration of the low-side driver 250 in the switching circuit 100. As described above, the calibration is performed by sequentially operating the low-side driver units DRL1 and DRL2.

FIG. 6 shows waveforms obtained when an i-th (i=1, 2) low-side driver unit DRLi is operated.

Prior to time t₀, the input signal IN is High, the upper arm 112 is on, the lower arm 114 is off, and the output voltage V_{OUT} is a High voltage V_{M}.

At time t₀, the input signal IN transitions from High to Low. The control circuit 210 controls the high-side driver 220 to turn off the upper arm 112. When the upper arm 112 is turned off at time t₁, a high-side-off signal HS_OFF is asserted.

In response to assertion of the high-side-off signal HS_OFF, the control circuit 210 controls a low-side driver unit DRLi of the low-side driver 250. As an output voltage V_{LGi} of the low-side driver unit DRLi rises, a gate-to-source voltage V_{LGSi} of the low-side transistor MLi increases. A rate of rise of the gate-to-source voltage V_{LGSi} depends on a drive strength of the low-side driver unit DRLi.

At time t₂, when the gate-to-source voltage V_{LGSi} exceeds a gate-to-source threshold voltage V_{GS(th)i} of the low-side transistor MLi, the low-side transistor MLi turns on and the output voltage V_{OUT} starts to decrease.

At time t₃, when the output voltage V_{OUT} becomes lower than the second threshold voltage V_{TH2}, a second output detection signal VOUTDET2 is asserted.

The timer circuit 290 measures, as a timing of assertion of the second output detection signal VOUTDET2, a time Toni from a change in the input signal IN to assertion of the second output detection signal VOUTDET2.

The timing Toni becomes slower as the gate-to-source threshold voltage V_{GS(th)i} of the transistor MLi becomes higher, and becomes faster as the gate-to-source threshold voltage V_{GS(th)i} becomes lower.

The control circuit 210 adjusts the drive strength of the low-side driver unit DRLi such that the timing Toni measured for a certain low-side driver unit DRLi matches a timing Tonj measured for another low-side driver unit DRLj.

That is, when Toni>Tonj, the control circuit 210 increases the drive strength of the low-side driver unit DRLi. As a result, the rate of rise of the gate-to-source voltage V_{LGSi} increases, whereby Toni can be shortened and brought closer to Tonj.

Conversely, when Toni<Tonj, the control circuit 210 decreases the drive strength of the low-side driver unit DRLi. As a result, the rate of rise of the gate-to-source voltage V_{LGSi} decreases, whereby Toni can be lengthened and brought closer to Tonj.

A procedure for adjusting the low-side driver units DRL1 and DRL2 is not particularly limited. For example, a time Ton1 measured first for the low-side driver unit DRL1 may be used as a reference, and the drive strength of the low-side driver unit DRL2 may be adjusted such that a time Ton2 measured for the low-side driver unit DRL2 approaches Ton1.

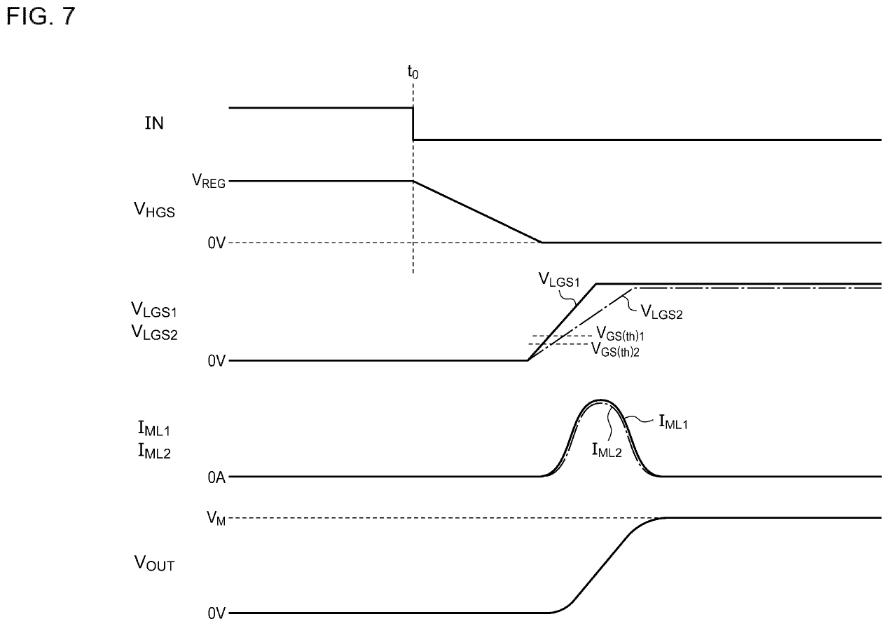

FIG. 7 illustrates operation of the switching circuit 100 after calibration. Prior to time t₀, the input signal IN is High, the lower arm 114 is off, the upper arm 112 is on, and the output voltage V_{OUT} is a High voltage V_{M}.

At time t₀, the input signal IN transitions from High to Low. The control circuit 210 controls the high-side driver 220 to turn off the upper arm 112. When the upper arm 112 is turned off at time t₁, a high-side-off signal HS_OFF is asserted.

In response to assertion of the high-side-off signal HS_OFF, the control circuit 210 controls the low-side driver 250 to turn on the lower arm 114.

After calibration, drive strengths of the low-side driver units DRL1 and DRL2 are optimized. Gate-to-source voltages V_{LGS1} and V_{LGS2} of the respective low-side transistors ML1 and ML2 rise with different slopes. By the calibration, the low-side transistors ML1 and ML2 turn on substantially simultaneously. This equalizes drain currents I_{ML1} and I_{ML2}, suppressing current concentration.

Next, a specific configuration example of the gate driver circuit 200 will be described.

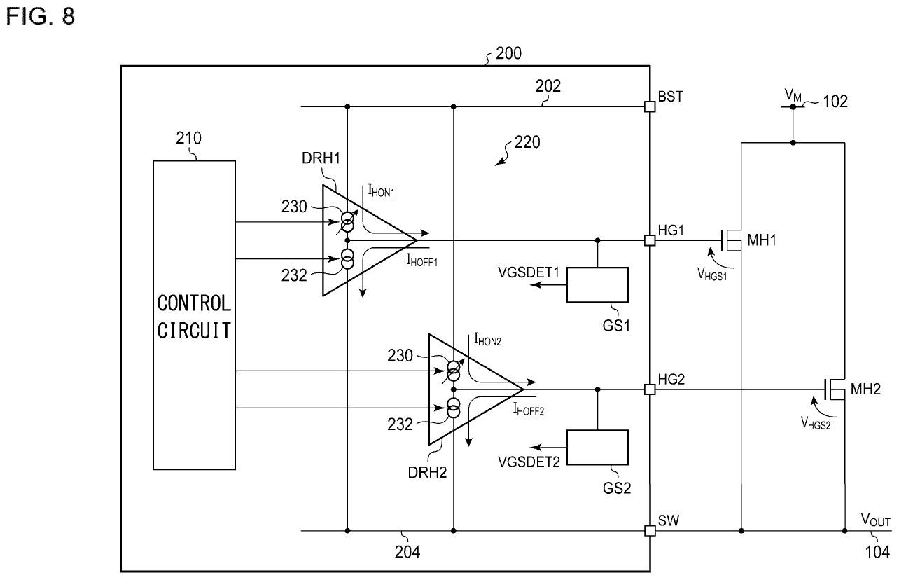

FIG. 8 is a circuit diagram of a gate driver circuit 200A according to one embodiment. Here, a configuration of the high-side driver 220 will be described, but the low-side driver 250 is configured similarly. The configuration of the low-side driver 250 can be understood by replacing “high-side” with “low-side”.

Each high-side driver unit DRHi includes a turn-on circuit 230 and a turn-off circuit 232. The turn-on circuit 230 becomes active when turning on the high-side transistor MHi and sources a turn-on current I_{HONi} to a gate of the high-side transistor MHi.

The turn-off circuit 232 becomes active when turning off the high-side transistor MHi and sinks a turn-off current I_{HOFFi} from the gate of the high-side transistor MHi.

As described above, each high-side driver unit DRHi is configured such that the drive strength is adjustable. In the example of FIG. 8, a magnitude of the turn-on current I_{HONi} generated by the turn-on circuit 230 is adjustable.

Further, a plurality of high-side gate sensors GS1 and GS2 are provided corresponding to the plurality of high-side driver units DRH1 and DRH2, respectively. A high-side gate sensor GSi compares a gate-to-source voltage V_{HGSi} of the corresponding high-side transistor MHi with a predetermined voltage V_{ON}, and asserts a high-side gate detection signal VGSDETi when the voltages V_{HGSi} and V_{ON} cross.

In this embodiment, each high-side driver unit DRHi is configured to vary a magnitude of the turn-on current I_{HONi} over time during turn-on operation of the high-side transistor MHi. That is, the turn-on current I_{HONi} is not constant, but varies in accordance with a waveform.

In one embodiment, each high-side driver unit DRHi varies the magnitude of the turn-on current I_{HONi} in three stages during turn-on operation of the high-side transistor MHi.

The control circuit 210 increases the magnitude of the turn-on current I_{HONi} generated by the high-side driver unit DRHi in response to assertion of the first output detection signal VOUTDET1.

The control circuit 210 also decreases the magnitude of the turn-on current I_{HONi} generated by the high-side driver unit DRHi in response to assertion of the high-side gate detection signal VGSDETi.

The above is the configuration of the gate driver circuit 200A. Next, operation thereof will be described.

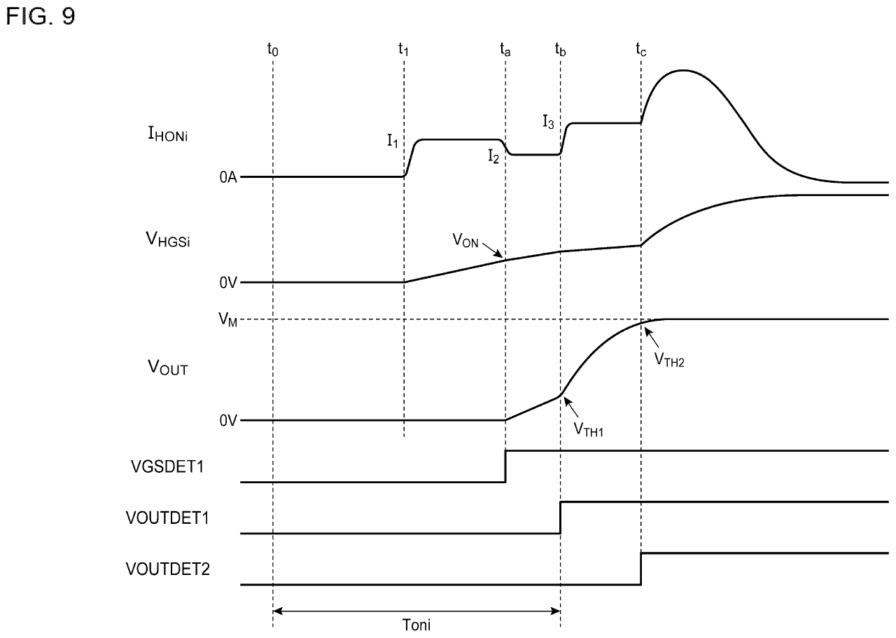

FIG. 9 illustrates operation waveforms of the gate driver circuit 200A shown in FIG. 8. At time t₁, the turn-on circuit 230 of the high-side driver unit DRHi becomes active. Immediately after becoming active, the turn-on circuit 230 generates a turn-on current I_{HONi} at a first current magnitude I₁.

When the gate-to-source voltage V_{HGSi} of the high-side transistor MHi exceeds the predetermined voltage V_{ON} at time tₐ, the high-side gate detection signal VGSDETi is asserted. In response, the control circuit 210 reduces the turn-on current I_{HONi} to a second current magnitude I₂.

After time tₐ, the output voltage V_{OUT} starts to rise. When the output voltage V_{OUT} exceeds the first threshold voltage V_{TH1} at time t_{b}, the first output detection signal VOUTDET1 is asserted. In response, the control circuit 210 increases the turn-on current I_{HONi} to a third current magnitude I₃.

When the output voltage V_{OUT} exceeds the second threshold voltage V_{TH2} at time t_{c}, the high-side driver unit DRHi applies a high voltage V_{BST} to the gate of the high-side transistor MHi.

In the above calibration, the timing of assertion of the first output detection signal VOUTDET1 is adjusted. That is, in the control shown in FIG. 9, the magnitudes of the turn-on currents I_{HON1} and I_{HON2} are adjusted such that the timing t_{b} becomes aligned among all of the high-side driver units DRH1 and DRH2.

As one example of adjusting the magnitude of the turn-on current I_{HONi}, the current magnitudes I₁, I₂, and I₃ may be scaled while maintaining their ratios. That is, the control circuit 210 may adjust an amplitude of a waveform of the calibration turn-on current I_{HONi} as the drive strength described above.

Next, a modified example of the gate driver circuit 200 will be described.

In addition, the gate sensors GS1 and GS2 in FIG. 8 may also serve as the high-side-off sensor 284.

In the embodiment, during calibration of the high-side driver units DRHi, the timer circuit 290 measures the timing of assertion of the output detection signal VOUTDET1 based on a change in the input signal IN. However, the present disclosure is not limited to this. For example, the timing of assertion of the output detection signal VOUTDET1 may be measured based on assertion of the low-side-off signal LS_OFF. That is, in the waveform diagram of FIG. 3, a period between times t₁ and t₃ may be measured by the timer circuit 290.

### Application

Next, applications of the switching circuit 100 will be described. The switching circuit 100 is suitably usable for a motor drive circuit.

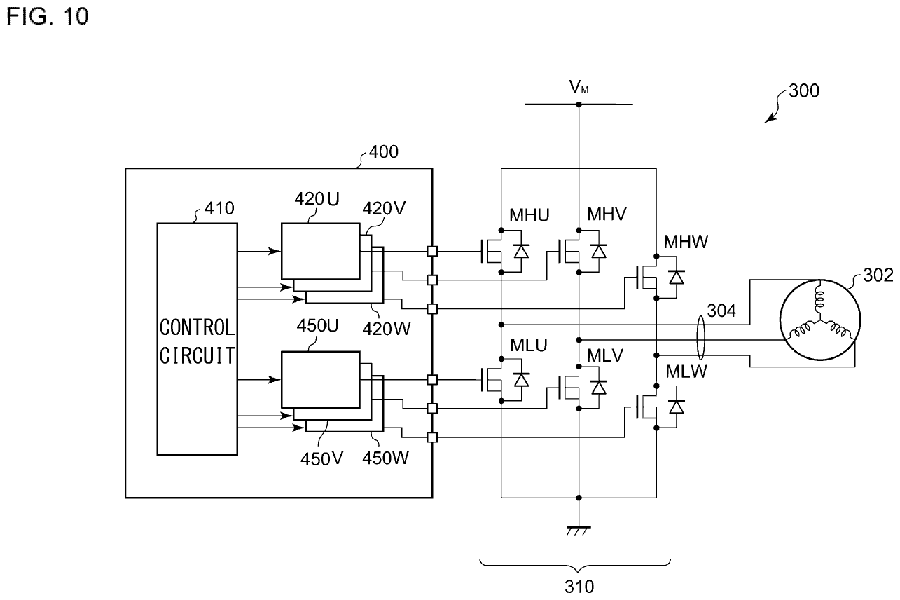

FIG. 10 is a circuit diagram of a motor drive apparatus 300 according to an embodiment. The motor drive apparatus 300 drives a three-phase motor 302 serving as a load and controls its rotational state.

The motor drive apparatus 300 includes a bridge circuit 310 and a gate driver circuit 400. The bridge circuit 310 is a three-phase inverter including U-phase, V-phase, and W-phase legs, and each phase leg includes a high-side transistor MH and a low-side transistor ML.

The gate driver circuit 400 includes a control circuit 410, and high-side drivers 420U to 420W and low-side drivers 450U to 450W. The control circuit 410 generates control signals indicating states of six arms constituting the bridge circuit 310, based on a state of the three-phase motor 302 serving as the load.

The high-side drivers 420U to 420W are configured according to the architecture of the high-side driver 220 described above. The low-side drivers 450U to 450W are configured according to the architecture of the low-side driver 250 described above.

Although a three-phase motor is used as an example here, a single-phase motor may also be used. In this case, the bridge circuit 310 becomes an H-bridge circuit.

Next, applications of the motor drive apparatus 300 will be described. The motor drive apparatus 300 may be used for control of a spindle motor of a hard disk, or control of a lens-driving motor of an imaging device. Alternatively, it can be used for driving a print-head motor or a paper-feed motor of a printer. Alternatively, the motor drive apparatus 300 may be used for driving a motor of an electric vehicle or a hybrid electric vehicle.

The embodiments are illustrative, and various modifications of combinations of the respective constituent elements and respective processing steps are possible. It will be understood by those skilled in the art that such modifications are also within the scope of the present disclosure and the present invention. Examples of such modifications will be described below.

### Modification 1

The power transistors may be configured as insulated gate bipolar transistors (IGBTs).

### Modification 2

The application of the switching circuit 100 is not limited to the motor drive apparatus 300. For example, the switching circuit 100 can be suitably used in a switching regulator (DC/DC converter), various power conversion devices (inverters and converters), lighting inverters for discharge lamps, and digital audio amplifiers. Accordingly, the switching circuit 100 can be used in consumer devices including electronic equipment and home appliances, as well as in automobiles and vehicle components, and industrial vehicles and industrial machines.

The embodiments described using specific terms are merely intended to illustrate the principles and applications of the present disclosure and invention, and numerous modifications and changes in arrangement will be allowed within the scope of the concept of the present disclosure and invention as defined by the claims.

### Additional Notes

The following technologies are disclosed in the present specification.

Item 1. A gate driver circuit configured to drive an inverter circuit including an upper arm formed by a plurality of parallel-connected high-side transistors, the gate driver circuit comprising:
a plurality of high-side driver units corresponding to the plurality of high-side transistors, each structured to supply a high-side drive voltage to a gate of a corresponding one of the high-side transistors;
a first output sensor structured to detect that an output voltage of the inverter circuit crosses a predetermined first threshold voltage and to assert a first output detection signal;
a control circuit structured to control the plurality of high-side driver units in response to an output command; and
a timer circuit structured to measure a timing of assertion of the first output detection signal,
wherein each of the plurality of high-side driver units has an adjustable drive strength, and
the control circuit is structured to adjust the drive strength of each of the plurality of high-side driver units such that the timings of assertion of the first output detection signal are aligned when each of the plurality of high-side driver units is operated individually.

Item 2. The gate driver circuit according to item 1, wherein the plurality of high-side driver units are each structured to supply a turn-on current to a gate of a corresponding one of the high-side transistors, and the drive strength is a magnitude of the turn-on current.

Item 3. The gate driver circuit according to item 2, wherein the plurality of high-side driver units are structured to vary the magnitude of the turn-on current over time, and an amplitude of a waveform of the turn-on current is adjustable as the drive strength.

Item 4. The gate driver circuit according to item 3, wherein the control circuit is structured to increase a magnitude of the turn-on current generated by the plurality of high-side driver units in response to the assertion of the first output detection signal.

Item 5. The gate driver circuit according to item 3 or 4, further comprising a plurality of high-side gate sensors corresponding to the plurality of high-side transistors and each structured to assert a high-side gate detection signal when a gate-to-source voltage of a corresponding one of the high-side transistors exceeds a predetermined voltage,
wherein the control circuit is structured to decrease a magnitude of the turn-on current generated by a corresponding high-side driver unit in response to the assertion of each high-side gate detection signal.

Item 6. The gate driver circuit according to any one of items 1 to 5, wherein a lower arm of the inverter circuit includes a plurality of parallel-connected low-side transistors, and the gate driver circuit further comprises:
a plurality of low-side driver units corresponding to the plurality of low-side transistors and each structured to generate a low-side drive voltage to a gate of a corresponding one of the low-side transistors; and
a second output sensor structured to detect that the output voltage of the inverter circuit crosses a predetermined third threshold voltage and to assert a second output detection signal,
wherein the control circuit is structured to control the plurality of low-side driver units in response to the output command;
each of the plurality of low-side driver units has an adjustable drive strength;
the timer circuit is structured to measure a timing of assertion of the second output detection signal; and
the control circuit is structured to adjust the drive strength of each of the plurality of low-side driver units such that the timings of assertion of the second output detection signal are aligned when each of the plurality of low-side driver units is operated individually.

Item 7. The gate driver circuit according to item 6, wherein the plurality of low-side driver units are each structured to supply a turn-on current to a gate of a corresponding one of the low-side transistors, and the drive strength is a magnitude of the turn-on current.

Item 8. The gate driver circuit according to item 7, wherein the plurality of low-side driver units are structured to vary the magnitude of the turn-on current over time, and an amplitude of a waveform of the turn-on current is adjustable as the drive strength.

Item 9. The gate driver circuit according to item 8, wherein the control circuit is structured to increase a magnitude of the turn-on current generated by the plurality of low-side driver units in response to the assertion of the second output detection signal.

Item 10. The gate driver circuit according to item 8 or 9, further comprising a plurality of low-side gate sensors corresponding to the plurality of low-side transistors and each structured to assert a low-side gate detection signal when a gate-to-source voltage of a corresponding one of the low-side transistors exceeds a predetermined voltage,
wherein the control circuit is structured to decrease a magnitude of the turn-on current generated by a corresponding low-side driver unit in response to the assertion of each low-side gate detection signal.

Item 11. The gate driver circuit according to any one of items 1 to 10, wherein the plurality of high-side transistors are SiC transistors.

Item 12. The gate driver circuit according to any one of items 1 to 10, wherein the plurality of high-side transistors are Si transistors.

Item 13. A gate driver circuit structured to drive an inverter circuit including a lower arm formed by a plurality of parallel-connected low-side transistors, the gate driver circuit comprising:
a plurality of low-side driver units corresponding to the plurality of low-side transistors and each structured to supply a low-side drive voltage to a gate of a corresponding one of the low-side transistors;
a second output sensor structured to detect that an output voltage of the inverter circuit crosses a predetermined third threshold voltage and to assert a second output detection signal;
a control circuit structured to control the plurality of low-side driver units in response to an output command; and
a timer circuit structured to measure a timing of assertion of the second output detection signal,
wherein each of the plurality of low-side driver units has an adjustable drive strength, and
the control circuit is structured to adjust the drive strength of each of the plurality of low-side driver units such that the timings of assertion of the second output detection signal are aligned when each of the plurality of low-side driver units is operated individually.

Item 14. The gate driver circuit according to any one of items 1 to 13, wherein the gate driver circuit is integrated on a single semiconductor substrate.

Item 15. A motor driving apparatus comprising:
a bridge circuit including an upper arm and a lower arm; and
the gate driver circuit according to any one of items 1 to 14 structured to drive the bridge circuit.

Item 16. an electronic apparatus comprising:
a motor; and
   the motor driving apparatus according to item 15 structured to drive the motor.

What is claimed is:

1. A gate driver circuit configured to drive an inverter circuit including an upper arm formed by a plurality of parallel-connected high-side transistors, the gate driver circuit comprising:
a plurality of high-side driver units corresponding to the plurality of high-side transistors, each structured to supply a high-side drive voltage to a gate of a corresponding one of the high-side transistors;
a first output sensor structured to detect that an output voltage of the inverter circuit crosses a predetermined first threshold voltage and to assert a first output detection signal;
a control circuit structured to control the plurality of high-side driver units in response to an output command; and
a timer circuit structured to measure a timing of assertion of the first output detection signal,
wherein each of the plurality of high-side driver units has an adjustable drive strength, and
the control circuit is structured to adjust the drive strength of each of the plurality of high-side driver units such that the timings of assertion of the first output detection signal are aligned when each of the plurality of high-side driver units is operated individually.

2. The gate driver circuit according to claim 1, wherein the plurality of high-side driver units are each structured to supply a turn-on current to a gate of a corresponding one of the high-side transistors, and the drive strength is a magnitude of the turn-on current.

3. The gate driver circuit according to claim 2, wherein the plurality of high-side driver units are structured to vary the magnitude of the turn-on current over time, and an amplitude of a waveform of the turn-on current is adjustable as the drive strength.

4. The gate driver circuit according to claim 3, wherein the control circuit is structured to increase a magnitude of the turn-on current generated by the plurality of high-side driver units in response to the assertion of the first output detection signal.

5. The gate driver circuit according to claim 3, further comprising a plurality of high-side gate sensors corresponding to the plurality of high-side transistors and each structured to assert a high-side gate detection signal when a gate-to-source voltage of a corresponding one of the high-side transistors exceeds a predetermined voltage,
wherein the control circuit is structured to decrease a magnitude of the turn-on current generated by a corresponding high-side driver unit in response to the assertion of each high-side gate detection signal.

6. The gate driver circuit according to claim 1, wherein a lower arm of the inverter circuit includes a plurality of parallel-connected low-side transistors, and the gate driver circuit further comprises:
a plurality of low-side driver units corresponding to the plurality of low-side transistors and each structured to generate a low-side drive voltage to a gate of a corresponding one of the low-side transistors; and
a second output sensor structured to detect that the output voltage of the inverter circuit crosses a predetermined third threshold voltage and to assert a second output detection signal,
wherein the control circuit is structured to control the plurality of low-side driver units in response to the output command;
each of the plurality of low-side driver units has an adjustable drive strength;
the timer circuit is structured to measure a timing of assertion of the second output detection signal; and
the control circuit is structured to adjust the drive strength of each of the plurality of low-side driver units such that the timings of assertion of the second output detection signal are aligned when each of the plurality of low-side driver units is operated individually.

7. The gate driver circuit according to claim 6, wherein the plurality of low-side driver units are each structured to supply a turn-on current to a gate of a corresponding one of the low-side transistors, and the drive strength is a magnitude of the turn-on current.

8. The gate driver circuit according to claim 7, wherein the plurality of low-side driver units are structured to vary the magnitude of the turn-on current over time, and an amplitude of a waveform of the turn-on current is adjustable as the drive strength.

9. The gate driver circuit according to claim 8, wherein the control circuit is structured to increase a magnitude of the turn-on current generated by the plurality of low-side driver units in response to the assertion of the second output detection signal.

10. The gate driver circuit according to claim 8, further comprising a plurality of low-side gate sensors corresponding to the plurality of low-side transistors and each structured to assert a low-side gate detection signal when a gate-to-source voltage of a corresponding one of the low-side transistors exceeds a predetermined voltage,
wherein the control circuit is structured to decrease a magnitude of the turn-on current generated by a corresponding low-side driver unit in response to the assertion of each low-side gate detection signal.

11. The gate driver circuit according to claim 1, wherein the plurality of high-side transistors are SiC transistors.

12. The gate driver circuit according to claim 1, wherein the plurality of high-side transistors are Si transistors.

13. A gate driver circuit structured to drive an inverter circuit including a lower arm formed by a plurality of parallel-connected low-side transistors, the gate driver circuit comprising:
a plurality of low-side driver units corresponding to the plurality of low-side transistors and each structured to supply a low-side drive voltage to a gate of a corresponding one of the low-side transistors;
a second output sensor structured to detect that an output voltage of the inverter circuit crosses a predetermined third threshold voltage and to assert a second output detection signal;
a control circuit structured to control the plurality of low-side driver units in response to an output command; and
a timer circuit structured to measure a timing of assertion of the second output detection signal,
wherein each of the plurality of low-side driver units has an adjustable drive strength, and
the control circuit is structured to adjust the drive strength of each of the plurality of low-side driver units such that the timings of assertion of the second output detection signal are aligned when each of the plurality of low-side driver units is operated individually.

14. The gate driver circuit according to claim 1, wherein the gate driver circuit is integrated on a single semiconductor substrate.

15. A motor driving apparatus comprising:
a bridge circuit including an upper arm and a lower arm; and
the gate driver circuit according to claim 1 structured to drive the bridge circuit.

16. An electronic apparatus comprising:
a motor; and
the motor driving apparatus according to claim 15 structured to drive the motor.
